(19) United States
(12) Patent Application Publication
(10) Pub. No.: US 2013/0229754 A1
(43) Pub. Date: Sep. 5, 2013

(54) CABINET AND CABINET ASSEMBLY

(71) Applicants: MING-YU LIU, Shenzhen City (CN); AN-GANG LIANG, Shenzhen City (CN)

(72) Inventors: MING-YU LIU, Shenzhen City (CN); AN-GANG LIANG, Shenzhen City (CN)

(73) Assignees: HON HAI PRECISION INDUSTRY CO., LTD., Tu-Cheng (TW); HONG FU JIN PRECISIN INDUSTRY (ShenZhen) CO., LTD., Shenzhen City (CN)

(21) Appl. No.: 13/473,626

(22) Filed: May 17, 2012

(30) Foreign Application Priority Data
Mar. 2, 2012 (CN) 201210052865.3

(51) Int. Cl. H05K 7/12; H05K 5/02

(52) U.S. Cl. 361/679.02; 312/257.1

(57) ABSTRACT

A cabinet includes two opposite horizontal brackets and a resilient plate. Each bracket includes a stop plate and a supporting plate. A through hole is defined in one of the stop plates adjacent to a front end of the stop plate. A first end of the resilient plate is mounted to an outer surface of said one of the stop plates adjacent to the through hole. A latching pole protrudes from an inner surface of the resilient plate. A distal end of the latching pole extends through the through hole and forms two slanted surfaces at front and rear sides of the distal end. When a server supported on the supporting plates is slid forwards to depart from the cabinet, the distal end of the latching pole engages in a latching hole of the server, to remind a user that the server will separate from the brackets.

### BACKGROUND

1. Technical Field

The present disclosure relates to a cabinet and a cabinet assembly.

2. Description of Related Art

Server cabinets usually include two opposite L-shaped brackets to support a server. However, when a user pulls the server outwards along the brackets, the user cannot accurately estimate when the server will disengage from the brackets, which may cause the server to fall off the brackets suddenly.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is a partial, exploded, isometric view of an exemplary embodiment of a cabinet assembly.

FIG. 2 is an enlarged view of a circled portion II of FIG. 1.

FIG. 3 is an enlarged view of a circled portion III of FIG. 1.

FIG. 4 is an assembled, isometric view of the cabinet assembly of FIG. 1.

FIG. 5 is an enlarged view of a circled portion V of FIG. 4.

FIG. 6 is similar to FIG. 4, but shows the cabinet assembly in another state.

FIG. 7 is an enlarged view of a circled portion VII of FIG. 6.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean at least one.

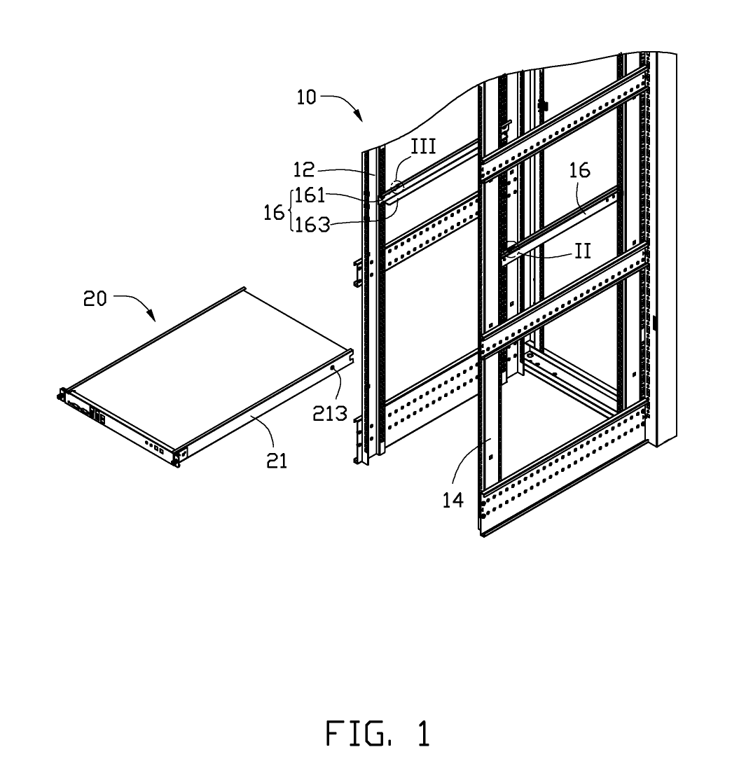

FIG. 1 shows an exemplary embodiment of a cabinet assembly including a cabinet 10 and a server 20.

The server 20 includes two opposite sidewalls 21. A latching hole 213 is defined in each sidewall 21, adjacent to the rear end of the sidewall 21.

The cabinet 10 includes two left posts 12 and two right posts 14. A horizontal bracket 16 is connected between the left posts 12, and another horizontal bracket 16 is connected between the right posts 14. Each bracket 16 includes an elongated stop plate 161 and a supporting plate 163 substantially perpendicularly extending inwards from the bottom of the stop plate 161. Opposite ends of each stop plate 161 are respectively connected to the corresponding left posts 12 or the corresponding right posts 14. The brackets 16 correspond to each other. The supporting plates 163 are coplanar and extend toward each other.

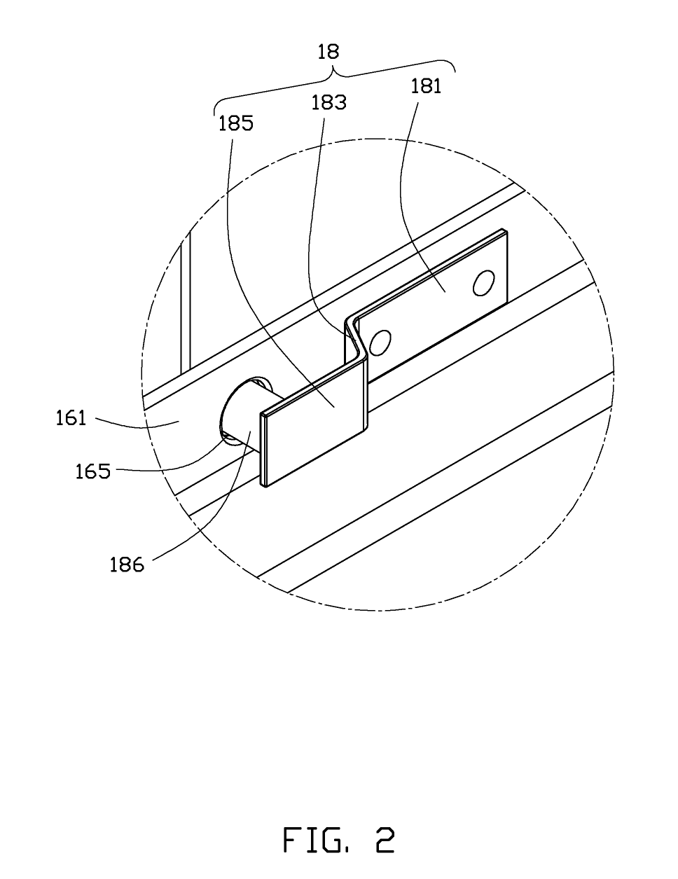

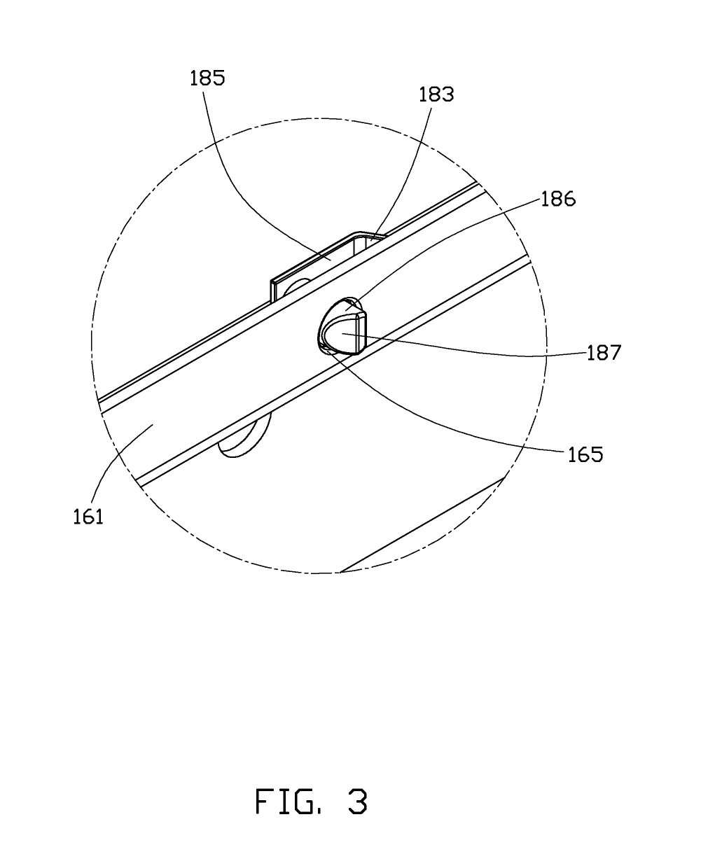

Referring to FIGS. 2 and 3, a resilient plate 18 is mounted to the outer surface of each stop plate 161, adjacent to the front end of the stop plate 161. Each resilient plate 18 includes a connecting portion 181 connected to the corresponding stop plate 161, a slanted portion 183 slantingly extending outwards and forwards from the front end of the connecting portion 181, and a resilient arm 185 extending forwards from the front end of the slanted portion 183. The resilient arm 185 is substantially parallel to the connecting portion 181. A through hole 165 is defined in each stop plate 161, facing the corresponding resilient arm 185. A latching pole 186 protrudes from the inner surface of each resilient arm 185. Distal ends of the latching poles 186 respectively extend through the through holes 165. The front and rear sides of the distal end of each latching pole 186 are cut to form two slanted surfaces 187. The slanted surfaces 187 of each latching pole 186 extend towards each other in a direction away from the resilient arm 185.

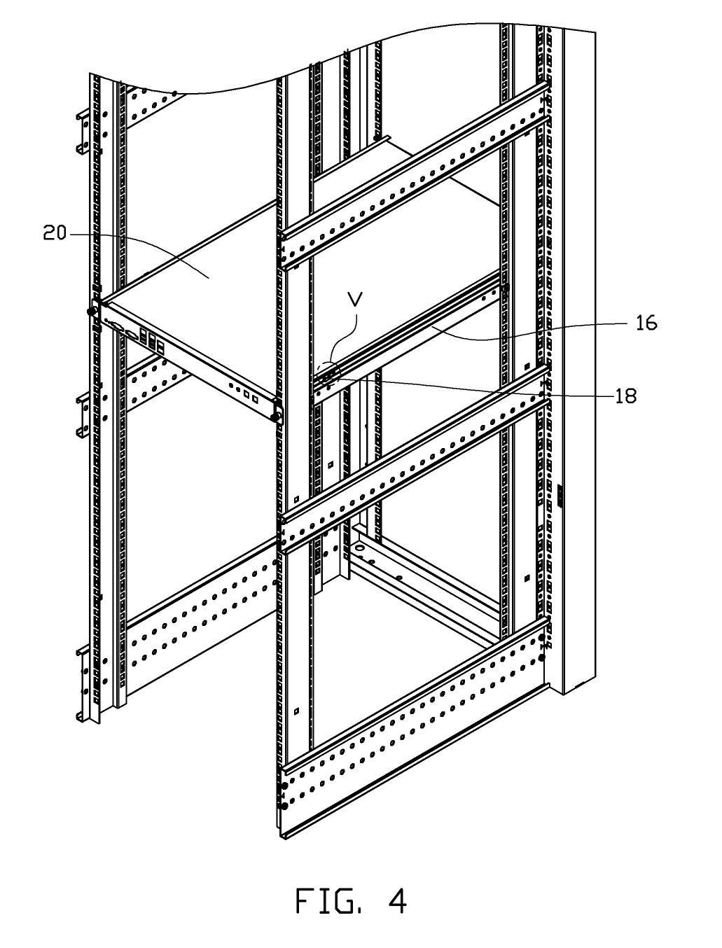

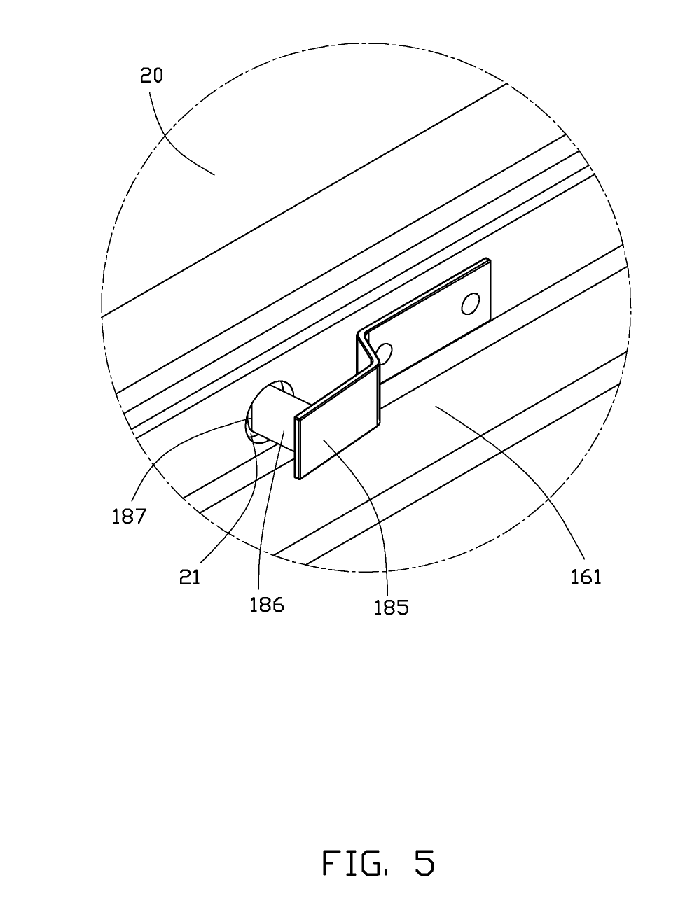

Referring to FIGS. 4 and 5, in assembly, the rear end of the server 20 is supported on the front ends of the supporting plates 163. The server 20 is pushed rearwards, opposite ends of the rear side of the server 20 respectively abut against the slanted surfaces 187 at the front sides of the latching poles 186 to deform the resilient arms 185 outwards. The distal ends of the latching poles 186 respectively engage with the sidewalls 21. When the latching holes 213 respectively align with the latching poles 186, the resilient arms 185 are restored to allow the distal ends of the latching poles 186 to respectively engage in the latching holes 213. The server 20 is stopped. The server 20 is pushed further rearwards, portions of the server 20 bounding the front ends of the latching holes 213 respectively abut against the slanted surfaces 187 at the front sides of the latching poles 186 to further deform the resilient arms 185 outwards. The distal ends of the latching poles 186 respectively disengage from the latching holes 213 and engage with the sidewalls 21. The server 20 can be completely received in the cabinet 10.

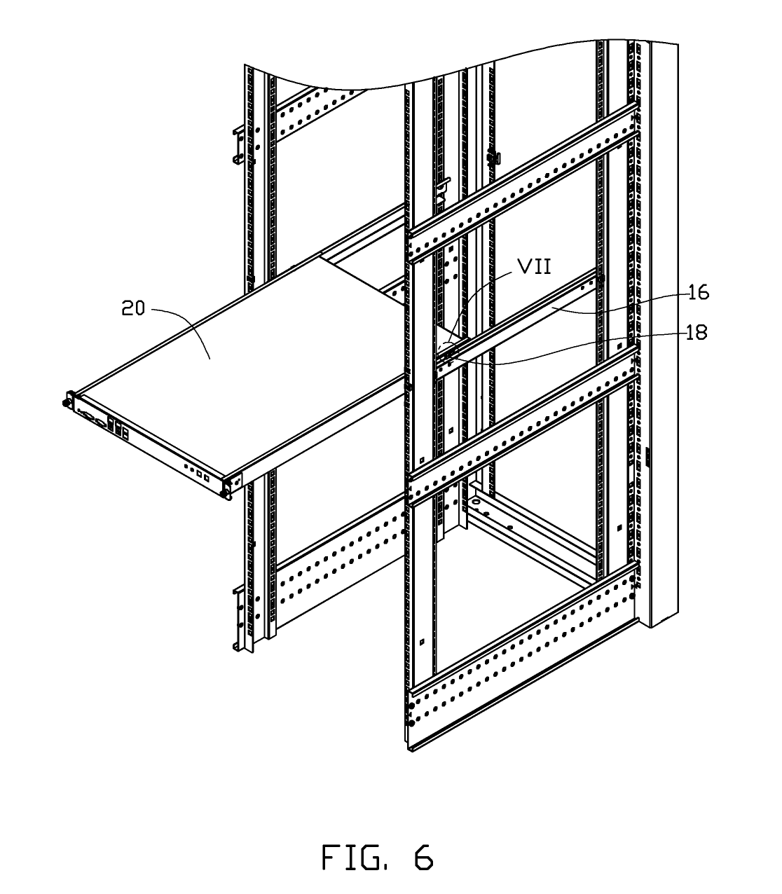

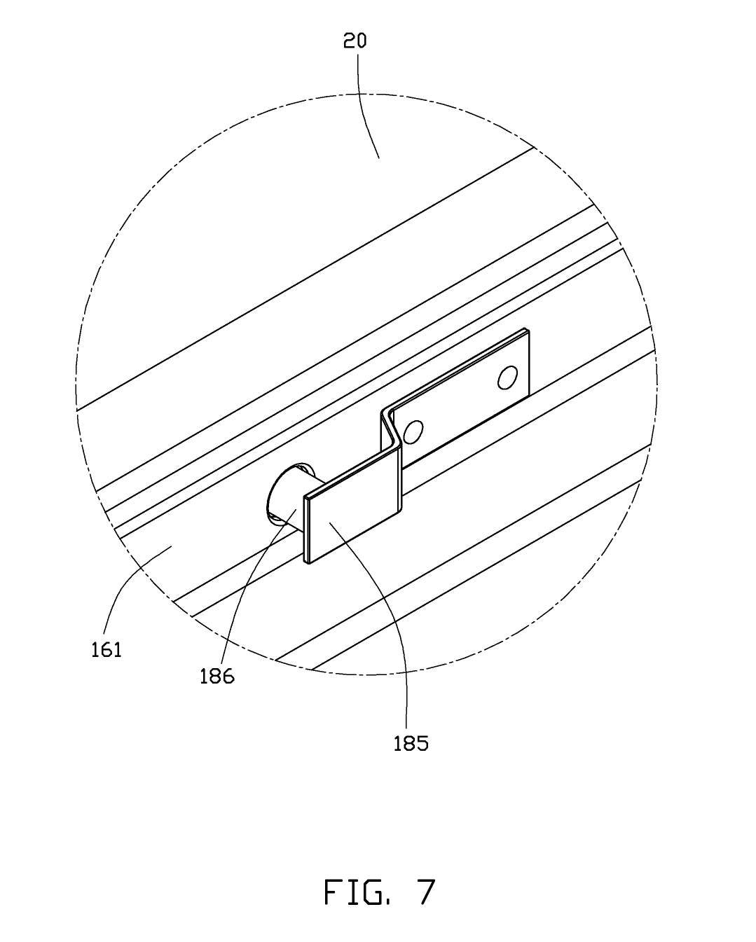

Referring to FIGS. 6 and 7, the server 20 is pulled out of the cabinet 10 under a first force by a user. When the latching holes 213 respectively align with the latching poles 186, the resilient arms 185 are restored to allow the distal ends of the latching poles 186 to respectively engage in the latching holes 213, to prevent the server 20 from further sliding when the server 20 is slid to a predetermined position. The user is reminded that the server 20 will departs from the brackets 16. The user carefully holds the server 20 and pulls the server 20 further forwards by a second force greater than the first force. Portions of the server 20 bounding the rear ends of the latching holes 213 respectively abut against the slanted surfaces 187 at the rear sides of the latching poles 186 to deform the resilient arms 185 outwards. The distal ends of the latching poles 186 respectively disengage from the latching holes 213 and engage with the sidewalls 21. The server 20 can separate from the cabinet 10.

Even though numerous characteristics and advantages of the embodiments have been set forth in the foregoing description, together with details of the structure and the functions of the embodiments, the disclosure is illustrative only, and changes may be made in details, especially in the matters of shape, size, and arrangement of parts within the principles of the embodiments to the full extent indicated by the broad general meaning of the terms in which the appended claims are expressed.

What is claimed is:

1. A cabinet, comprising:
two opposite horizontal brackets each comprising a stop plate, and a supporting plate extending inwards from a bottom of the stop plate, wherein a through hole is defined in one of the stop plates adjacent to a front end of the stop plate; and
a resilient plate, wherein a first end of the resilient plate is mounted to an outer surface of said one of the stop plates adjacent to the through hole, a latching pole protrudes from an inner surface of a second end of the resilient plate away from the first end, a distal end of the latching pole extends through the through hole and forms two opposite slanted surfaces respectively at front and rear sides of the distal end, the slanted surfaces extend towards each other in a direction away from the resilient plate.

2. The cabinet of claim 1, wherein the resilient plate comprises a connecting portion, a slanted portion slantingly extending outwards from the connecting portion, and a resilient arm extending from an end of the slanted portion away from the connecting portion, the connecting portion is mounted to the outer surface of said one of the stop plates, the latching pole protrudes from an inner surface of the resilient arm.

3. The cabinet of claim 2, wherein the resilient arm is substantially parallel to the connecting portion.

4. The cabinet of claim 2, wherein the resilient arm is in front of the connecting portion.

5. The cabinet of claim 1, further comprising two left posts and two right posts, wherein the brackets are respectively connected between the left posts and between the right posts.

6. A cabinet assembly, comprising:
a cabinet comprising two opposite horizontal brackets, wherein each of the bracket comprises a stop plate and a supporting plate extending inwards from a bottom of the stop plate, a through hole is defined in one of the stop plates adjacent to a front end of the stop plate, a first end of a resilient plate is mounted to an outer surface of the said one of the stop plates adjacent to the through hole, a latching pole protrudes from a second end of the resilient plate away from the first end, a distal end of the latching pole extends through the through hole and forms two opposite slanted surfaces respectively at front and rear sides of the distal end, and the slanted surfaces extend towards each other in a direction away from the resilient plate; and
a server comprising two opposite sidewalls, wherein a latching hole is defined in one of the sidewalls adjacent to a rear end of the sidewall, the server is received in the cabinet and supported on the supporting plates, the resilient plate is deformed to allow the distal end of the latching pole to abut against a corresponding one of the sidewalls when the server is slid forwards under a first force to depart from the cabinet, the resilient plate is restored to allow the distal end of the latching pole to engage in the latching hole to prevent the server from further sliding when the server is slid to a predetermined position; and the slanted surface at the rear side of the latching pole abuts against a portion of the server bounding the latching hole to allow the distal end of the latching pole to overcome the engagement between the latching hole and the latching pole under a second force such that the server separates from the supporting plates.

7. The cabinet assembly of claim 6, wherein the resilient plate comprises a connecting portion, a slanted portion slantingly extending outwards from the connecting portion, and a resilient arm extending from an end of the slanted portion away from the connecting portion, the connecting portion is mounted to the outer surface of said one of the stop plates, the latching pole protrudes from an inner surface of the resilient arm.

8. The cabinet assembly of claim 7, wherein the resilient arm is substantially parallel to the connecting portion.

9. The cabinet assembly of claim 7, wherein the resilient arm is in front of the connecting portion.

10. The cabinet assembly of claim 6, wherein the cabinet further comprises two left posts and two right posts, the brackets are respectively connected between the left posts and between the right posts.
